(19) United States
(12) Patent Application Publication
(10) Pub. No.: US 2020/0395401 A1
(43) Pub. Date: Dec. 17, 2020

(54) FOWBCSP CMOS CHIP MODULE WITH A PACKAGING STRUCTURE

(71) Applicant: SHIH-CHI CHEN, Taipei City (TW)

(72) Inventor: SHIH-CHI CHEN, Taipei City (TW)

(21) Appl. No.: 17/005,296

(22) Filed: Aug. 27, 2020

Related U.S. Application Data
(63) Continuation-in-part of application No. 16/246,567, filed on Jan. 14, 2019.

(51) Int. Cl. H01L 27/146

(52) U.S. Cl. CPC H01L 27/14636; H01L 27/14618; H01L 27/14643

(57) ABSTRACT

A FOWBCSP CMOS chip module with a packaging structure includes a CMOS chip having plural joints and a light sensing area on an upper side thereof; two stop bars positioned on the upper side of the CMOS chip; a substrate installed on the upper side of the CMOS chip; the joints and the light sensing area being located within a through hole of the substrate; and an upper side of the substrate being formed with a plurality of joints; a plurality of conductive wires passing through the through holes of the substrate for connecting the joints of the substrate and the joints of the CMOS chip; and a glass installed on an upper side of the light sensing area. The glass exposes out and external light can radiate the CMOS chip through the glass; and the joints on the upper side of the substrate have a plurality of conductive balls.

The present invention is an application of continuation in part (CIP) of U.S. patent application Ser. No. 16/246,567, filed at Jan. 14, 2019, which is invented by and assigned to the applicant of the present invention, and thus the contents of the U.S. patent application Ser. No. 16/246,567 are incorporated into the present invention as a part of the present invention.

### FIELD OF THE INVENTION

The present invention is related to chips, and in particular to a FOWBCSP CMOS chip module with a packaging structure.

### BACKGROUND OF THE INVENTION

In the prior art semiconductor packaging structure, a chip has a plurality of joints on an upper side of the chip and a substrate has a plurality of joints on an upper side of the substrate. The joints of the chip are connected to the joints of the substrate by using a plurality of conductive wires. The substrate has through holes which are sealed by conductive material so that the joints of the substrate are guided to a bottom side of the substrate. A circuit board is placed on the bottom side of the substrate. The circuit board has a plurality of joints to be connected to the joints guided to the bottom side of the substrate so as to form an electrical connection therebetween.

During a process of packaging, it is necessary to form a large packaging structure to enclose the chip and the substrate so as to avoid the conductive wires to expose out. As a result, higher cost is needed and time for manufacturing is prolonged.

Moreover, the substrate must have a large number of through holes which are filled fully by conductive material. Each of the through holes should not be connected to each other for avoiding short-circuit. Therefore, the process of packaging is time-consuming and work-consuming. Moreover, above process also increase the whole cost in manufacturing.

To resolve the above disadvantages in the prior art, the present invention introduces a brand new FOWBCSP chip module with a packaging structure and manufacturing method of the same.

### SUMMARY OF THE INVENTION

To improve the defects in the prior art, the present invention provides a FOWBCSP CMOS chip module with a packaging structure, wherein only one through hole is used for receiving a plurality of conductive wires. Therefore, the manufacturing time period is shortened and the cost for manufacturing is reduced greatly. Furthermore, in the present invention, the joints are arranged on an upper side of the substrate and the joints are connected to the joints of the CMOS chip through conductive wires; or joints are arranged on the upper side and lower side of the substrate and the upper joints are connected to the lower joints and the lower joints are connected to the joints of the CMOS chip; or at least one side of the substrate is extended to the outer side of the CMOS chip and the lower side of the substrate is arranged with joints which is connected to the joints of the CMOS chip and the circuit at a lower side of the substrate. Furthermore, in packaging of the present invention, it is only needed to package exposed conductive wires. The packaging area is smaller. The cost and labor hours are saved due to the packaging way. Moreover, the lengths of the conductive wires are shorter and most of them are hidden in the through holes. No conductive wire exposes out and thus the safety of the arrangement is high. only one through hole is used for receiving a plurality of conductive wires. Therefore, the manufacturing time period is shortened and the cost for manufacturing is reduced greatly. Furthermore, in the present invention, the joints are arranged on an upper side of the substrate and the joints are connected to the joints of the CMOS chip through conductive wires; or joints are arranged on the upper side and lower side of the substrate and the upper joints are connected to the lower joints and the lower joints are connected to the joints of the CMOS chip; or at least one side of the substrate is extended to the outer side of the CMOS chip and the lower side of the substrate is arranged with joints which is connected to the joints of the CMOS chip and the circuit at a lower side of the substrate. Furthermore, in packaging of the present invention, it is only needed to package exposed conductive wires. The packaging area is smaller. The cost and labor hours are saved due to the packaging way. Moreover, the lengths of the conductive wires are shorter and most of them are hidden in the through holes. No conductive wire exposes out and thus the safety of the arrangement is high.

To achieve above object, the present invention provides a FOWBCSP CMOS chip module with a packaging structure, comprising: a CMOS chip having a plurality of joints and a light sensing area on an upper side thereof; two stop bars positioned on the upper side of the CMOS chip and at two sides of the light sensing area; a substrate installed on the upper side of the CMOS chip; the substrate having a penetrating through hole; the joints and the light sensing area of the CMOS chip being located within the through hole so that light can radiate the light sensing area through the through hole; and an upper side of the substrate being formed with a plurality of joints; a plurality of conductive wires passing through the through holes of the substrate for connecting the joints of the substrate and the joints of the CMOS chip; and a glass installed on an upper side of the light sensing area; and wherein the through holes of the substrate is sealed by gluing material to form a second packaging structure; the second packaging structure does not cover the glass, so that the glass exposes out and external light can radiate the CMOS chip directly through the glass; and the joints on the upper side of the substrate have a plurality of conductive balls.

### BRIEF DESCRIPTION OF THE DRAWINGS

FIG. 1A is an exploded schematic view about the CMOS chip, substrate and circuit board in the first embodiment of the present invention.

FIG. 1B is a schematic cross sectional view showing the arrangement of the elements in the first embodiment of the present invention.

FIG. 1C is a schematic cross section view showing the element assembly of the application embodiment showing in FIG. 1B.

FIG. 2A is an exploded schematic view about the CMOS chip, substrate and circuit board in the second embodiment of the present invention.

FIG. 2B is a schematic cross sectional view showing the arrangement of the elements in the second embodiment of the present invention.

FIG. 2C is a schematic cross section view showing the element assembly of the application embodiment showing in FIG. 2B.

FIG. 3A is an exploded schematic view about the CMOS chip, substrate and circuit board in the third embodiment of the present invention.

FIG. 3B is a schematic cross sectional view showing the arrangement of the elements in the third embodiment of the present invention.

FIG. 3C is a schematic cross section view showing the element assembly of the application embodiment showing in FIG. 3B.

FIG. 4A is an exploded schematic view about the CMOS chip, substrate and circuit board in the fourth embodiment of the present invention.

FIG. 4B is a schematic cross sectional view showing the arrangement of the elements in the fourth embodiment of the present invention.

FIG. 4C is a schematic cross section view showing the element assembly of the application embodiment showing in FIG. 4B.

### DETAILED DESCRIPTION OF THE INVENTION

In order that those skilled in the art can further understand the present invention, a description will be provided in the following in details. However, these descriptions and the appended drawings are only used to cause those skilled in the art to understand the objects, features, and characteristics of the present invention, but not to be used to confine the scope and spirit of the present invention defined in the appended claims.

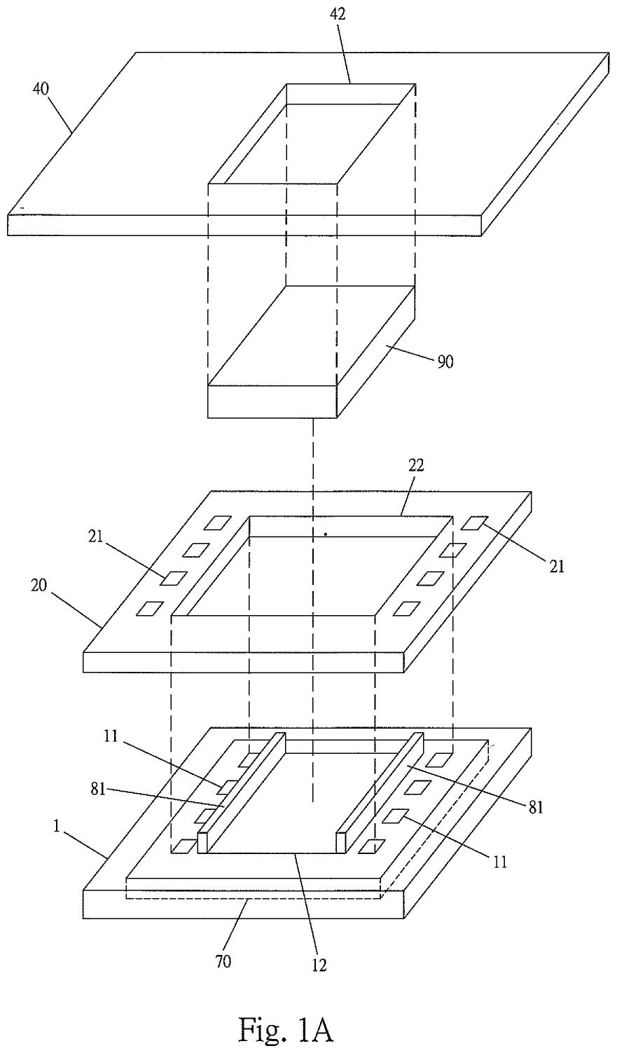

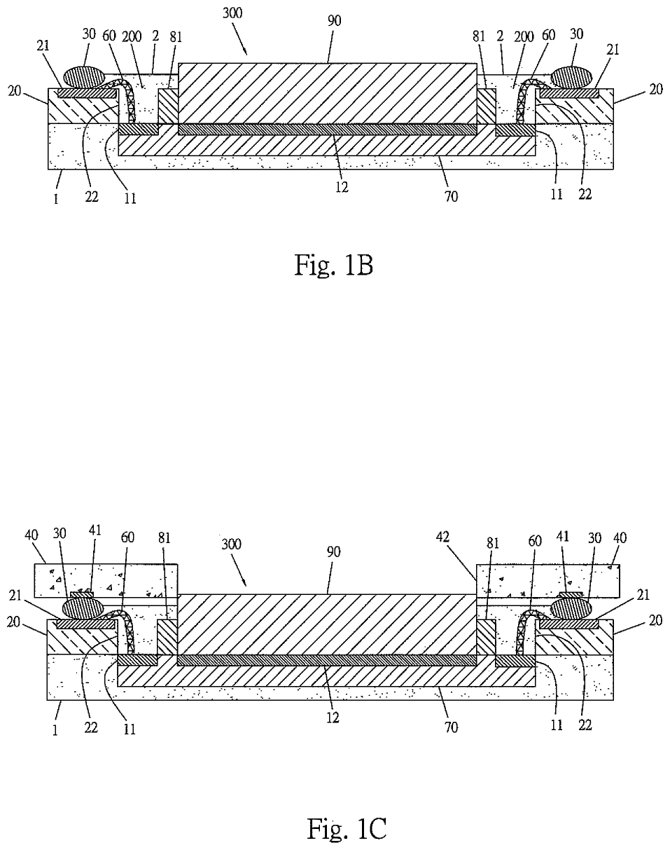

With reference to FIGS. 1A to 1C, the structure 300 of the first embodiment of the present invention is illustrated. The present invention includes the following elements.

A CMOS chip 70 has a plurality of joints 11 and a light sensing area 12 on an upper side thereof.

A first packaging structure 1 is formed on a lower side and lateral sides of the CMOS chip 70.

Two stop bars 81 are positioned on the upper side of the CMOS chip 71 and at two sides of the light sensing area 12.

A substrate 20 is installed on the upper side of the CMOS chip 70. The substrate 20 has a penetrating through hole 22. The joints 11 and the light sensing area 12 of the CMOS chip 70 are located within the through hole 22 so that light may radiate the light sensing area 12 through the through hole 22; and an upper side of the substrate 20 is formed with a plurality of joints 21. A plurality of conductive wires 60 pass through the through holes 22 of the substrate 20 for connecting the joints 21 of the substrate 20 and the joints 11 of the CMOS chip 70.

A glass 90 is installed between the two stop bars 81 and on an upper side of the light sensing area 12.

The through holes 22 of the substrate 20 is sealed by gluing material 200 to form a second packaging structure 2. The second packaging structure 2 does not cover the glass 90, so that the glass 90 exposes out and external light can radiate the CMOS chip 70 directly through the glass 90.

The joints 21 on the upper side of the substrate 20 have a plurality of conductive balls 30 (tin balls or solder balls).

As shown in FIG. 1C, a circuit board 40 may be arranged on an upper side of the substrate 20. The circuit board 40 is a soft board. The circuit board 40 is formed with a penetrating hole 42 which is positioned corresponding to that of the glass 90. Thereby, external light may pass through the penetrating hole 42 and the glass 90 to radiate the CMOS chip 70. The conductive balls 30 on the upper side of the joint 21 of the substrate 20 are guided to the joints 41 on the circuit board 40 so as to form electric connection therebetween.

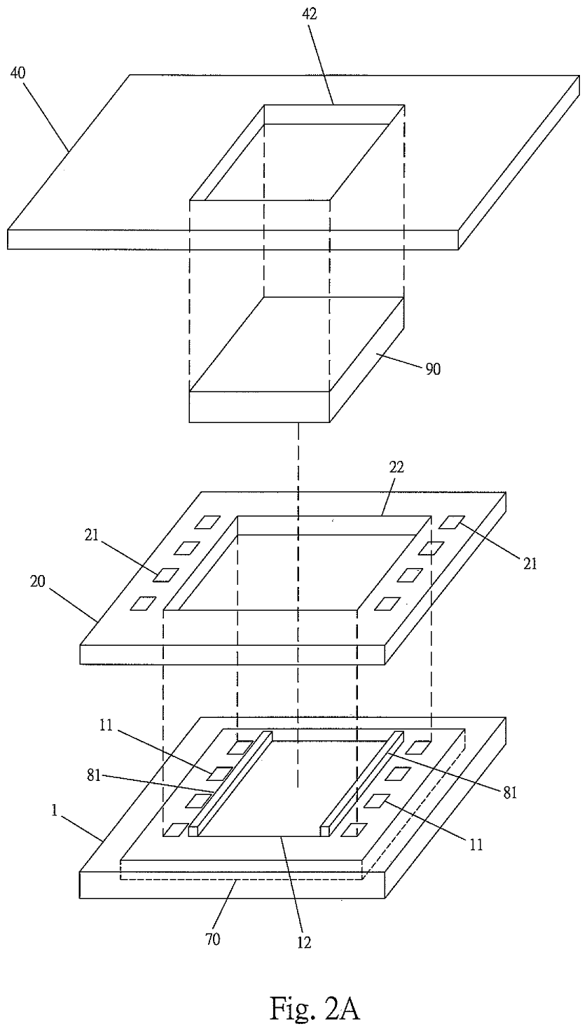

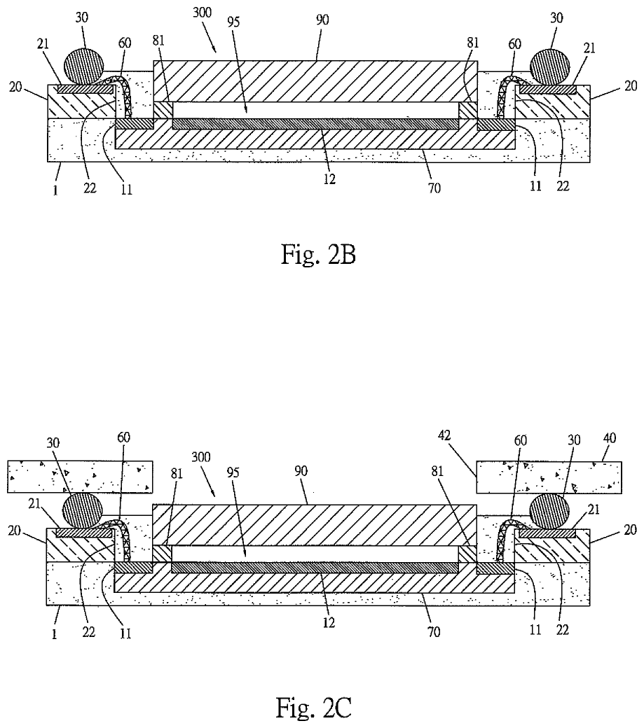

FIGS. 2A to 2C describes the second embodiment of the present invention, the elements in this embodiment identical to the above said embodiment are numbered with same numbers which have identical functions and thus the details of these elements are not further described here.

In this embodiment, the glass 90 is positioned on an upper side of the two stop bars 81 and a gap 95 is formed between the glass 90 and the CMOS chip 70.

Referring to FIG. 2C, in this embodiment, a circuit board 40 is arranged on an upper side of the substrate 20. The conductive balls 30 on the upper side of joints 21 on the substrate 20 are connected to the joints 41 of the circuit board 40.

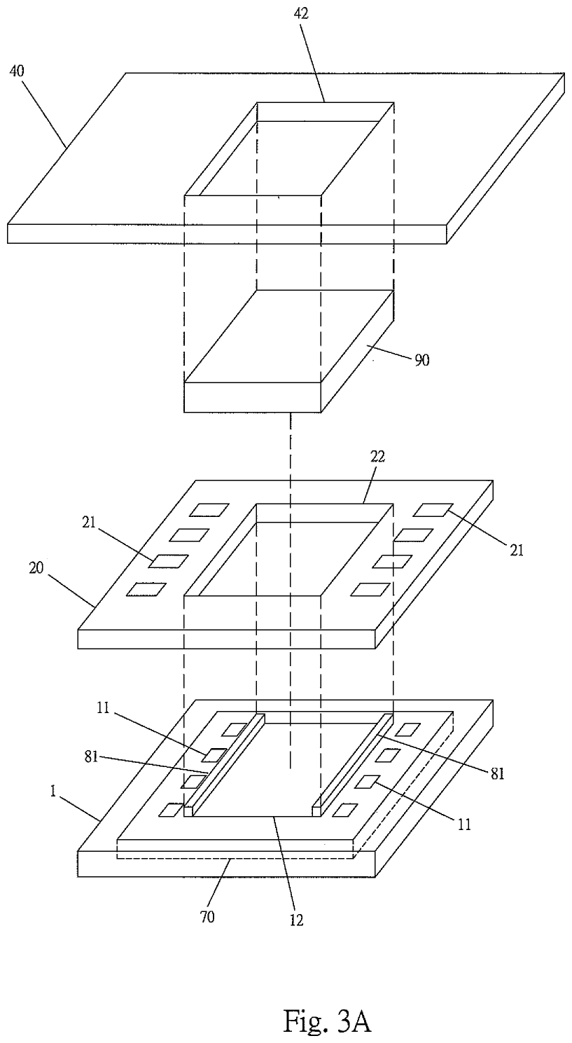

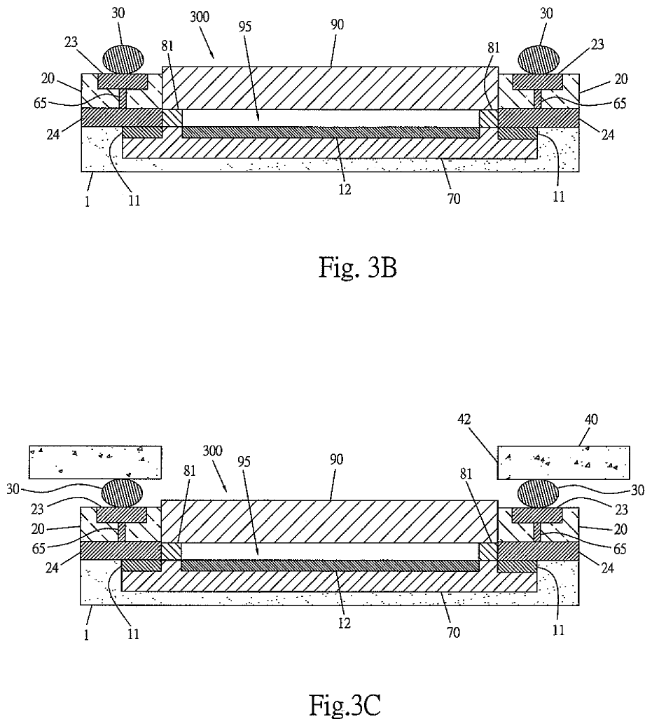

Referring to FIGS. 3A to 3C, the third embodiment of the present invention is illustrated. In this embodiment, the conductive wires 60 are not used, while joints 11 are arranged on an upper side of the substrate 20 and are connected to the joints 11 on an upper side of the CMOS chip 70. This embodiment includes the following elements.

A CMOS chip 70 has a plurality of joints 11 and a light sensing area 12 on an upper side thereof.

A first packaging structure 1 is formed on a lower side and lateral sides of the CMOS chip 70.

Two stop bars 81 are positioned on the upper side of the CMOS chip 71 and at two sides of the light sensing area 12.

A substrate 20 is installed on the upper side of the CMOS chip 70. The substrate 20 has a penetrating through holes 22. The light sensing area 12 of the CMOS chip 70 and the two stop bars 81 are located within the through hole 22 so that light may radiate the light sensing area 12 through the through hole 22; and an upper side of the substrate 20 is formed with a plurality of joints 23 and a lower side of the substrate 20 is formed with a plurality of joints 24. The joints 24 on the lower side of the substrate 20 are connected to the joints 11 on the upper side of the substrate 20.

A glass 90 is installed between the two stop bars 81 and is formed with a gap 95 between the glass 90 and the CMOS chip 70. Therefore, external light can incident into the glass 90 to radiate on the CMOS chip 70.

The joints 23 on the substrate 20 are formed with conductive balls 30 (such as tin balls or welding balls).

As shown in FIG. 3C, a circuit board 40 may be arranged on an upper side of the substrate 20. The circuit board 40 is a soft board. The circuit board 40 is formed with a penetrating hole 42 which is positioned corresponding to that of the glass 90. Thereby, external light may pass through the penetrating hole 42 and the glass 90 to radiate the CMOS chip 70. The conductive balls 30 on the upper side of the joint 21 of the substrate 20 are guided to the joints 41 on the circuit board 40 so as to form electric connection therebetween.

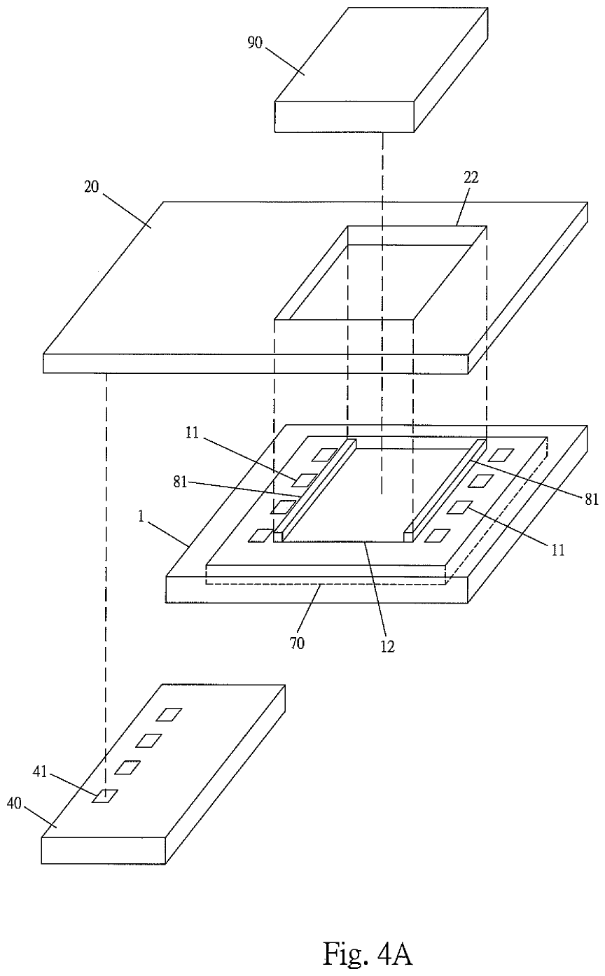

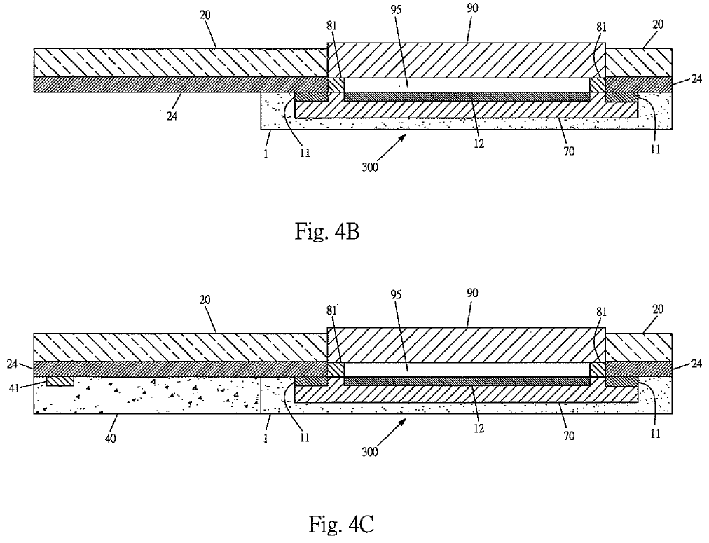

With reference to FIGS. 4A to 4C, the fourth embodiment of the present invention is illustrated. In this embodiment, the substrate 20 is extended to an outer side of the CMOS chip 70. A lower side of the CMOS chip 70 is formed with joints 24 for connecting to the joints 11 on an upper side of the CMOS chip 70 and the joints 41 on the circuit board 40. This embodiment includes the following elements.

A CMOS chip 70 has a plurality of joints 11 and a light sensing area 12 on an upper side thereof.

A first packaging structure 1 is formed on a lower side and lateral sides of the CMOS chip 70.

Two stop bars 81 are positioned on the upper side of the CMOS chip 71 and at two sides of the light sensing area 12.

A substrate 20 is installed on the upper side of the CMOS chip 70. The substrate 20 has a penetrating through hole 22. The light sensing area 12 of the CMOS chip 70 and the two stop bars 81 are located within the through hole 22 so that light may radiate the light sensing area 12 through the through hole 22; and a lower side of the substrate 20 is formed with a plurality of joints 24. The joints 24 on the lower side of the substrate 20 are connected to the joints 11 on the upper side of the substrate 20.

At least one side of the substrate 20 and the joints 24 on the side of substrate 20 extends to an outer side of the CMOS chip 70.

A glass 90 is installed between the two stop bars 81 and is formed with a gap 95 between the glass 90 and the CMOS chip 70.

Therefore, external light may directly radiate the CMOS chip 70 by passing through the glass 90.

Referring to FIG. 4C, in application, a circuit board 40 is arranged on a lower side of the extending end of the substrate 20. The joints 24 on the extending end of the substrate 20 are connected to the joints 41 of the circuit board 40 so that the circuit board 40 is electrically connected to the CMOS chip 70.

In the present invention, a plurality of CMOS chips 70 can be connected in parallel and above mentioned packaging structure is formed around the CMOS chips 70 and all other structures are identical to the above mentioned. Therefore, the details will not be further described herein.

Advantages of the present invention are that only one through hole is used for receiving a plurality of conductive wires. Therefore, the manufacturing time period is shortened and the cost for manufacturing is reduced greatly. Furthermore, in the present invention, the joints are arranged on an upper side of the substrate and the joints are connected to the joints of the CMOS chip through conductive wires; or joints are arranged on the upper side and lower side of the substrate and the upper joints are connected to the lower joints and the lower joints are connected to the joints of the CMOS chip; or at least one side of the substrate is extended to the outer side of the CMOS chip and the lower side of the substrate is arranged with joints which is connected to the joints of the CMOS chip and the circuit at a lower side of the substrate. Furthermore, in packaging of the present invention, it is only needed to package exposed conductive wires. The packaging area is smaller. The cost and labor hours are saved due to the packaging way. Moreover, the lengths of the conductive wires are shorter and most of them are hidden in the through holes. No conductive wire exposes out and thus the safety of the arrangement is high.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A FOWBCSP CMOS chip module with a packaging structure, comprising:
a CMOS chip having a plurality of joints and a light sensing area on an upper side thereof;
two stop bars positioned on the upper side of the CMOS chip and at two sides of the light sensing area;
a substrate installed on the upper side of the CMOS chip; the substrate having a penetrating through hole; the joints and the light sensing area of the CMOS chip being located within the through hole so that light can radiate the light sensing area through the through hole; and an upper side of the substrate being formed with a plurality of joints; a plurality of conductive wires passing through the through holes of the substrate for connecting the joints of the substrate and the joints of the CMOS chip; and
a glass installed on an upper side of the light sensing area; and
wherein the through holes of the substrate is sealed by gluing material to form a second packaging structure; the second packaging structure does not cover the glass, so that the glass exposes out and external light can radiate the CMOS chip directly through the glass; and the joints on the upper side of the substrate have a plurality of conductive balls.

2. The FOWBCSP CMOS chip module with a packaging structure as claimed in claim 1, wherein the glass is installed between the two stop bars.

3. The FOWBCSP CMOS chip module with a packaging structure as claimed in claim 1, wherein the glass is positioned on an upper sides of the two stop bars and a gap is formed between the glass and the CMOS chip.

4. The FOWBCSP CMOS chip module with a packaging structure as claimed in claim 1, wherein the first packaging structure is formed on a lower side and lateral sides of the CMOS chip.

5. The FOWBCSP CMOS chip module with a packaging structure as claimed in claim 1, wherein the conductive balls are tin balls or solder balls.

6. The FOWBCSP CMOS chip module with a packaging structure as claimed in claim 1, further comprising: a circuit board is arranged on an upper side of the substrate; the circuit board is formed with a penetrating hole which is positioned corresponding to that of the glass; thereby, external light passes through the penetrating hole and the glass to radiate the CMOS chip; the conductive balls on the upper side of the joint of the substrate are guided to the joints on the circuit board so as to form electric connection therebetween.

7. The FOWBCSP CMOS chip module with a packaging structure as claimed in claim 1, wherein the circuit board is a soft board.

8. A FOWBCSP CMOS chip module with a packaging structure, comprising:
a CMOS chip having a plurality of joints and a light sensing area on an upper side thereof;
two stop bars being positioned on the upper side of the CMOS chip and at two sides of the light sensing area;
a substrate installed on the upper side of the CMOS chip; the substrate having a penetrating through holes; the light sensing area of the CMOS chip and the two stop bars being located within the through hole so that light radiates the light sensing area through the through hole; and an upper side of the substrate being formed with a plurality of joints and a lower side of the substrate being formed with a plurality of joints; the joints on the lower side of the substrate being connected to the joints on the upper side of the substrate; and
a glass being installed between the two stop bars and being formed with a gap between the glass and the CMOS chip; therefore, external light can incident into the glass to radiate on the CMOS chip.

9. The FOWBCSP CMOS chip module with a packaging structure as claimed in claim 8, further comprising a first package structure positioned on a lower side and lateral sides of the CMOS chip.

10. The FOWBCSP CMOS chip module with a packaging structure as claimed in claim 8, wherein the conductive balls are tin balls or welding balls.

11. The FOWBCSP CMOS chip module with a packaging structure as claimed in claim 8, further comprising a circuit board arranged on an upper side of the substrate; the circuit board being formed with a penetrating hole which is positioned corresponding to that of the glass; thereby, external light passes through the penetrating hole and the glass to radiate the CMOS chip; the conductive balls on the upper side of the joint of the substrate being guided to the joints on the circuit board so as to form electric connection therebetween.

12. The FOWBCSP CMOS chip module with a packaging structure as claimed in claim 11, wherein the circuit board being a soft board.

13. AFOWBCSP CMOS chip module with a packaging structure comprising:
A CMOS chip having a plurality of joints and a light sensing area on an upper side thereof.
two stop bars being positioned on the upper side of the CMOS chip and at two sides of the light sensing area;
a substrate installed on the upper side of the CMOS chip; the substrate having a penetrating through hole; the light sensing area of the CMOS chip and the two stop bars being located within the through hole so that light can radiate the light sensing area through the through hole; and a lower side of the substrate being formed with a plurality of joints; the joints on the lower side of the substrate being connected to the joints the upper side of the substrate; at least one side of the substrate and the joints on the at least one side of the substrate being extended out of the CMOS chip; and
a glass installed at upper sides of two stop bars and a gap being formed between the glass and the CMOS chip; as a result, external light can directly radiate the CMOS chip through the glass.

14. The FOWBCSP CMOS chip module with a packaging structure as claimed in claim 12, further comprising a first packaging structure formed on a lower side and lateral sides of the CMOS chip.

15. The FOWBCSP CMOS chip module with a packaging structure as claimed in claim 13, further comprising a circuit board arranged on a lower side of the substrate; the joints on the extending end of the substrate being connected to the joints of the circuit board so that the circuit board is electrically connected to the CMOS chip.

16. The FOWBCSP CMOS chip module with a packaging structure as claimed in claim 15, wherein the circuit board is a soft board.
